(19) United States
(12) Patent Application Publication
(10) Pub. No.: US 2005/0116231 A1
(43) Pub. Date: Jun. 2, 2005

(54) Thin film transistor and method of manufacturing the same

(76) Inventors: Tae-Wook Kang, Seongnam-si (KR); Sang-Il Park, Seoul (KR)

Correspondence Address: MCGUIREWOODS, LLP, 1750 TYSONS BLVD, SUITE 1800, MCLEAN, VA, 22102, US

(21) Appl. No.: 10/971,162

(22) Filed: Oct. 25, 2004

(30) Foreign Application Priority Data
Nov. 27, 2003 (KR) 2003-84785

(51) Int. Cl. H01L 29/76

(52) U.S. Cl. 257/72

(57) ABSTRACT

A thin film transistor and method of manufacturing the same is disclosed. In the thin film transistor and method of manufacturing the same, an organic planarization layer and an inorganic layer may be sequentially formed, over an entire surface of the substrate, on the source/drain electrode of a thin film transistor having a semiconductor layer, a gate, source/drain areas and the source/drain electrodes. After forming a photoresist pattern on the inorganic layer, an etching process may be performed to cover the organic planarization layer to form a contact hole or a via hole that connects a pixel electrode to one of the source/drain electrodes. According to the manufacturing method of the present invention, the contact hole or via hole, formed using two or more masks conventionally, can be formed using one mask, thereby simplifying a process, and improving an adhesion with the pixel electrode through the inorganic layer, and also improving a sealing adhesion in the encapsulation process to increase the lifetime of the resultant thin film transistor. This thin film transistor can be appropriately applied to the active matrix organic electroluminescent display.

### CROSS-REFERENCE TO RELATED APPLICATION

This application claims priority to and the benefit of Korean Patent Application No. 2003-84785, filed Nov. 27, 2003, the disclosure of which is incorporated herein by reference in its entirety.

### BACKGROUND OF THE INVENTION

1. Field of the Invention

The present invention generally relates to a thin film transistor and method of manufacturing the same wherein, when forming a via hole of a semiconductor device, an organic planarization layer and an inorganic layer may be sequentially deposited to reduce the number of masks and to simplify etching.

2. Description of the Related Art

Among flat panel displays, organic light-emitting displays (OLED) may have advantages such as wider temperature range, superior shock and vibration resistance, faster response time, and wider viewing angle. Thus these displays may be capable of providing a clearer moving picture. For this reason, OLEDs may be a suitable next generation technology for flat panel displays.

OLEDs can be classified as passive matrix type where a separate driving source may be required, and an active matrix type in which a thin film transistor serving as a switching device may be incorporated. This classification is thus based on the driving method of the OLED.

FIG. 1 is a cross-sectional view of an active type organic electroluminescent display. In the method of manufacturing the organic electroluminescent display having the above structure, first, a thin film transistor having a buffer layer (not shown), a semiconductor layer 11, a gate 13, source/drain areas 14-1, 14-2, an interlayer insulating layer 15 and source/drain electrodes 17-1, 17-2 may be formed on a substrate 10 by a set of semiconductor manufacturing processes.

Next, an inorganic layer 18-1, such as SiNx, may be deposited as a passivation layer 18 to cover the source/drain electrodes 17-1, 17-2 on the substrate 10 where the thin film transistor may be formed. Subsequently, after forming a photoresist pattern on the inorganic layer 18-1, a contact hole or a via hole 19-1 connected to the source/drain electrodes 17-1, 17-2 may be formed by an etching process using the photoresist pattern as a mask. After forming the contact hole or via hole 19-1, the photoresist pattern may be removed by the process such as oxygen plasma or photoresist strip processes.

Next, after forming a photosensitive type or etching type organic planarization layer 18-2 on the contact hole or via hole 19-1 and forming the photoresist pattern, a mask etching process may be performed to the photoresist pattern to form the contact hole or via hole 19 connected to a pixel electrode 20 of a subsequent process.

Next, after forming a conductive material on substantially the entire surface of the substrate 10, the typical photolithography process may be performed along with exposure, developing and etching processes, and the pixel electrode 20 where the source/drain electrodes 141-, 14-2 may be connected through the contact hole or via hole 19 may be formed.

Next, a planarization layer 21 may be formed on substantially the entire surface of the substrate 10 to cover the pixel electrode 20, and then, an opening 22 may be formed to expose the pixel electrode 20.

Subsequently, by forming an organic layer and an upper electrode on the pixel electrode 20 using the conventional process, the active matrix organic electroluminescent display may be manufactured.

As such, the passivation layer 18 that protects the source/drain electrodes 14-1, 14-2 and that includes the contact hole or via hole 10 connected to the pixel electrode 20 may be formed by two etching processes using the inorganic layer 18-1 and the organic planarization layer 18-2, wherein the etching process may be for fully removing the organic planarization layer 18-2 that might be left on a portion where a sealant may be deposited in the subsequent encapsulation process. As a result, there may be a problem that two or more etching processes should be performed using at least two masks in order to form the contact hole or via hole 20 that connects the pixel electrode 20 to the source/drain electrodes 17-1, 17-2.

However, as illustrated in FIG. 2, as can be seen from the cross section of the thin film transistor in the SEM photograph, a lifting failure can be generated between the organic planarization layer 18-2 and the pixel electrode 20. Like this, when the organic planarization layer 18-2 may be used as a passivation layer 18, the lifting failure of the layer may be generated due to a poor adhesion with the pixel electrode 20, and accordingly, delamination and crack of the pixel electrode can be made due to a physical shock in the process such as cleaning and stripping, thereby causing device failures.

### SUMMARY OF THE INVENTION

The present invention provides a thin film transistor in which an adhesion between a passivation layer on source/drain electrodes and a pixel electrode may be improved.

The present invention further provides a thin film transistor in which a sealing adhesion after the encapsulation process may be improved.

The present invention further provides a thin film transistor that may have an increased lifetime.

The present invention further provides a thin film transistor wherein an organic planarization layer and an inorganic layer may be sequentially formed as a passivation layer between the source/drain electrodes and the pixel electrode.

The present invention further provides a thin film transistor wherein a first inorganic layer, an organic planarization layer and a second inorganic layer may be sequentially formed as a passivation layer between the source/drain electrodes and the pixel electrode.

The present invention further provides a thin film transistor wherein, in forming the contact hole or via hole that connects the pixel electrode to one of the source/drain electrodes, the number of masks can be reduced.

The present invention further provides an active matrix organic electroluminescent display wherein an organic planarization layer and an inorganic layer may be sequentially formed as a passivation layer between one of the source/drain electrodes and the pixel electrode.

The present invention further provides an active matrix organic electroluminescent display wherein a first inorganic layer, an organic planarization layer and a second inorganic layer may be sequentially formed as a passivation layer between one of the source/drain electrodes and the pixel electrode.

In an exemplary embodiment, the present invention may be characterized by a thin film transistor wherein a passivation layer may be formed between a pixel electrode and source/drain electrodes of a thin film transistor having a semiconductor layer, a gate, source/drain areas and the source/drain electrodes, and includes an inorganic layer and an organic planarization layer, and wherein a portion of the inorganic layer of the passivation layer directly contacts with the pixel electrode, and the organic planarization layer placed below the inorganic layer contacts with the source/drain electrodes.

Specifically, the present invention may be characterized by a thin film transistor comprising: a semiconductor layer formed on an insulating substrate; a gate insulating layer formed on the substrate having the semiconductor layer; a gate electrode formed on a gate insulating layer over the semiconductor layer; source/drain areas formed in the semiconductor layer of both sides of the gate; an interlayer insulating layer formed on substantially the entire surface of the substrate and having a contact hole/via hole that exposes source/drain electrodes; the source/drain electrodes formed on the interlayer insulating layer and contacting with the source/drain areas through the contact hole/via hole; and a passivation layer having a contact hole or a via hole that exposes one of the source/drain electrodes wherein an organic planarization layer and an inorganic layer may be sequentially formed on substantially the entire surface of the substrate.

In one embodiment the contact hole or via hole that exposes one of the source/drain electrodes does not have a step.

In another exemplary embodiment, the present invention may be characterized by a thin film transistor wherein a passivation layer may be formed between a pixel electrode and source/drain electrodes of a thin film transistor having a semiconductor layer, a gate, source/drain areas and the source/drain electrodes, and includes a first inorganic layer, an organic planarization layer and a second inorganic layer, and the contact hole or via hole connects one of the source/drain electrode to a pixel electrode.

Specifically, the present invention may be characterized by a thin film transistor comprising: a semiconductor layer formed on an insulating substrate; a gate insulating layer formed on the substrate having the semiconductor layer; a gate formed on a gate insulating layer over the semiconductor layer; source/drain areas formed in the semiconductor layer of both sides of the gate; an interlayer insulating layer formed on substantially the entire surface of the substrate and having a contact hole/via hole that exposes source/drain electrodes; the source/drain electrodes formed on the interlayer insulating layer and contacting with the source/drain areas through the contact hole/via hole; and a passivation layer having a contact hole or a via hole that exposes one of the source/drain electrodes and having a first inorganic layer, an organic planarization layer and a second inorganic layer sequentially formed on substantially the entire surface of the substrate.

In one embodiment the contact hole or via hole that exposes one of the source/drain electrodes does not have a step.

In yet another exemplary embodiment, the present invention may be characterized by a method of manufacturing a thin film transistor, comprising: forming a semiconductor layer on an insulating substrate; forming a gate insulating layer on the substrate having the semiconductor layer; forming a gate on the gate insulating layer formed on the semiconductor layer; ion-implanting impurities into the semiconductor layer to form source/drain areas in the semiconductor layer of both sides of the gate; forming an interlayer insulating layer on substantially the entire surface of the substrate; etching a selected area of the interlayer insulating layer to form a contact hole/via hole that exposes the source/drain areas; forming source/drain electrodes that contact with the source/drain areas through the contact hole/via hole on the interlayer insulating layer; sequentially forming an organic planarization layer and an inorganic layer as a passivation layer on substantially the entire surface of the substrate; and etching a selected area of the organic planarization layer and the organic layer to form a contact hole or a via hole that exposes one of the source/drain electrodes.

In one embodiment a photoresist pattern layer may be formed on the passivation layer having the organic planarization layer and the inorganic layer, and the contact hole or via hole may be formed by the etching process using one mask.

In yet another exemplary embodiment, the present invention may be characterized by a method of manufacturing a thin film transistor, comprising: forming a semiconductor layer on an insulating substrate; forming a gate insulating layer on the substrate having the semiconductor layer; forming a gate on the gate insulating layer placed on the semiconductor layer; ion-implanting high-concentration impurities into the semiconductor layer to form source/drain areas in the semiconductor layer of both sides of the gate; forming an interlayer insulating layer on substantially the entire surface of the substrate; etching a selected area of the interlayer insulating layer to form a contact hole/via hole that exposes the source/drain areas; forming source/drain electrodes that contact with the source/drain areas through the contact hole/via hole on the interlayer insulating layer; sequentially forming a first inorganic layer, an organic planarization layer and a second inorganic layer as a passivation layer on substantially the entire surface of the substrate; and etching a selected area of the first inorganic layer, the organic planarization layer and the second inorganic layer to form a contact hole or a via hole that exposes one of the source/drain electrodes.

In one embodiment a photoresist pattern layer may be formed on the first inorganic layer, the organic planarization layer and the second inorganic layer, and the contact hole or via hole may be formed by the etching process using one mask.

In yet another exemplary embodiment, the present invention may be characterized by an active matrix organic electroluminescent display comprising: a semiconductor layer formed on an insulating substrate; a gate insulating layer formed on the substrate having the semiconductor layer; a gate formed on the gate insulating layer over the semiconductor layer; source/drain areas formed in the semiconductor layer of both sides of the gate; an interlayer insulating layer formed on substantially the entire surface of the substrate and having a contact hole/via hole that exposes source/drain electrodes; source/drain electrodes formed on the interlayer insulating layer and contacting with the source/drain areas through the contact hole/via hole; a passivation layer having a contact hole or a via hole that exposes one of the source/drain electrodes and having an organic planarization layer and an inorganic layer sequentially formed on substantially the entire surface of the substrate; a planarization layer formed on substantially the entire surface of the substrate and having an opening; and a pixel electrode formed to extend through a contact hole or a via hole from one of the source/drain electrodes and exposed through the opening.

In one embodiment the contact hole or via hole that exposes one of the source/drain electrodes does not have a step.

In yet another exemplary embodiment, the present invention may be characterized by an active matrix organic electroluminescent display comprising: a semiconductor layer formed on an insulating substrate; a gate insulating layer formed on the substrate having the semiconductor layer; a gate formed on the gate insulating layer over the semiconductor layer; source/drain areas formed in the semiconductor layer of both sides of the gate; an interlayer insulating layer formed on substantially the entire surface of the substrate and having a contact hole/via hole that exposes source/drain electrodes; source/drain electrodes formed on the interlayer insulating layer and contacting with the source/drain areas through the contact hole and/or the via hole; a passivation layer having a contact hole or a via hole that exposes one of the source/drain electrodes and having a first inorganic layer, an organic planarization layer and a second inorganic layer sequentially formed on substantially the entire surface of the substrate as the passivation layer; a planarization layer formed on substantially the entire surface of the substrate and having an opening; and a pixel electrode formed to extend through a contact hole or a via hole from one of the source/drain electrodes and exposed through the opening.

In one embodiment the contact hole or via hole that exposes one of the source/drain electrodes does not have a step.

### BRIEF DESCRIPTION OF THE DRAWINGS

The above and other features of the present invention will be described in reference to certain exemplary embodiments thereof with reference to the attached drawings in which:

FIG. 1 is a cross-sectional view of an active matrix organic electroluminescent display.

FIG. 2 is a SEM photograph showing a section of the thin film transistor of the active matrix organic electroluminescent display of FIG. 1.

FIGS. 3A to 3D are cross-sectional views illustrating a method of manufacturing a thin film transistor according to a first embodiment of the present invention.

FIG. 4 is a cross-sectional view of a thin film transistor according to a second embodiment of the present invention.

FIG. 5 is a cross-sectional view of an active matrix organic electroluminescent display having a thin film transistor according to a first embodiment of the present invention.

FIG. 6 is a cross-sectional view of an active matrix organic electroluminescent display having a thin film transistor according to a second embodiment of the present invention.

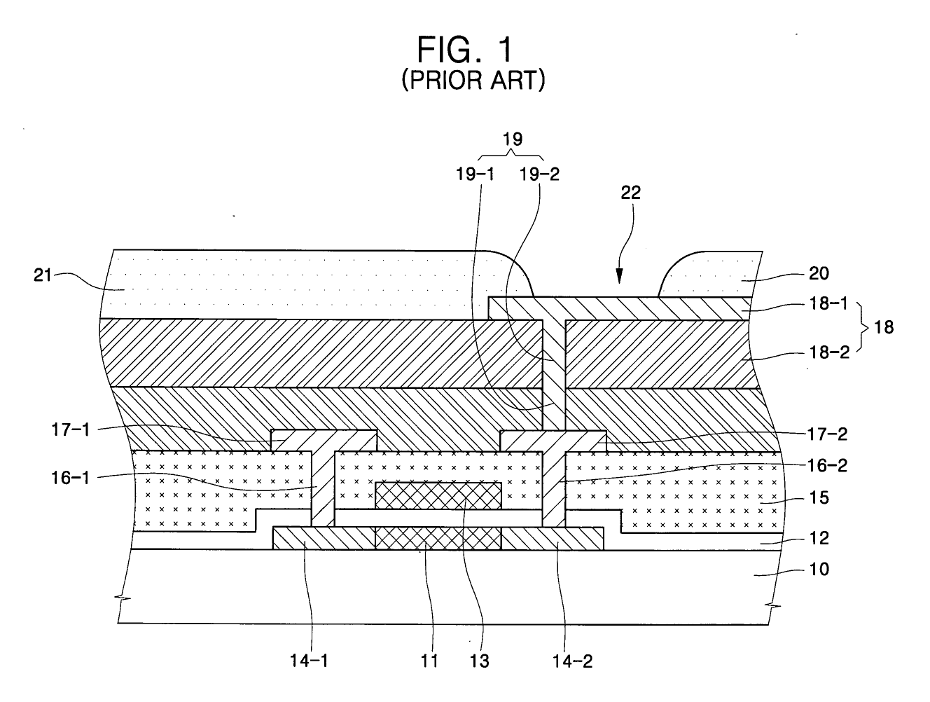

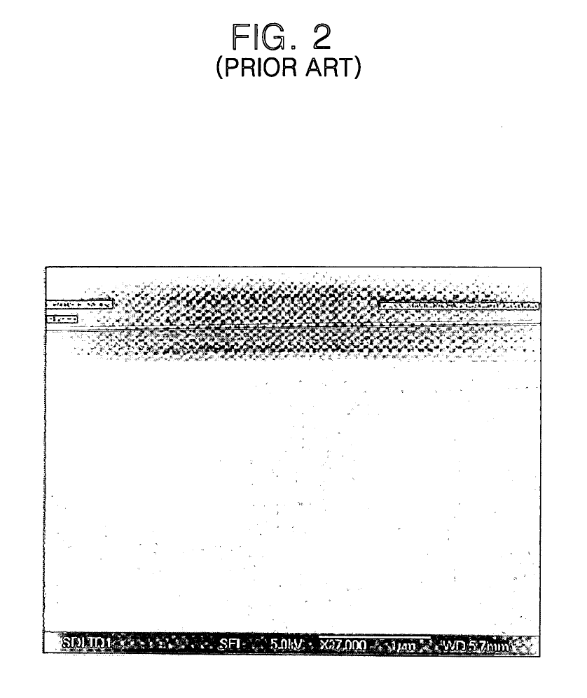

### DETAILED DESCRIPTION OF THE INVENTION

The present invention will now be described more fully hereinafter with reference to the accompanying drawings, in which several embodiments of the invention are shown. This invention may, however, be embodied in different forms and should not be construed as limited to the embodiments set forth herein. Rather, these embodiments are provided to aid in properly describing the invention to those skilled in the art. In the drawings, the thickness of layers and regions may be exaggerated for clarity. Like numbers refer to like elements throughout the specification.

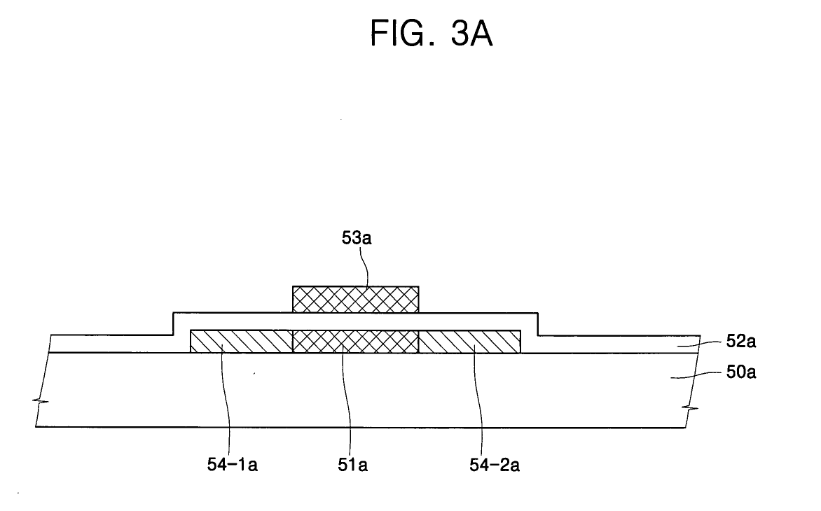

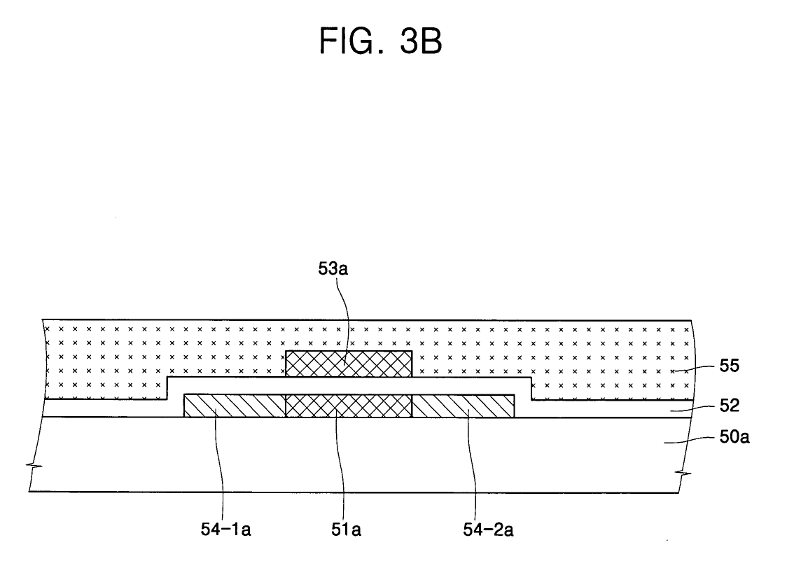

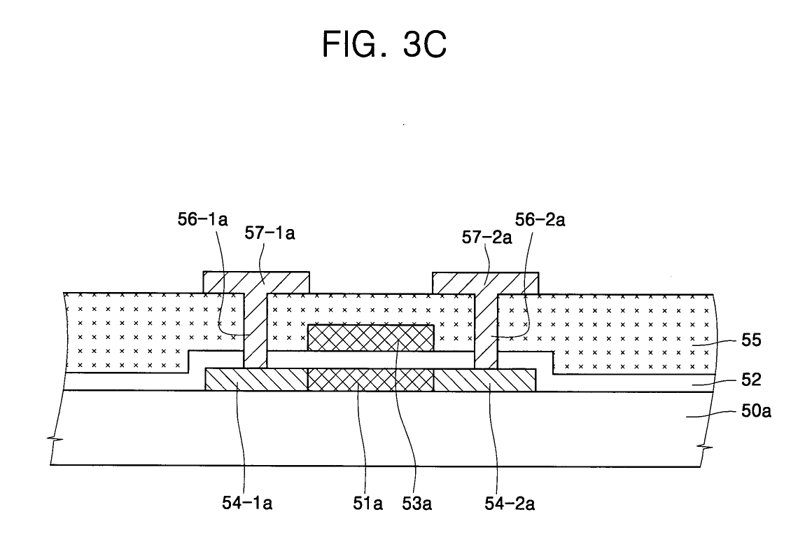

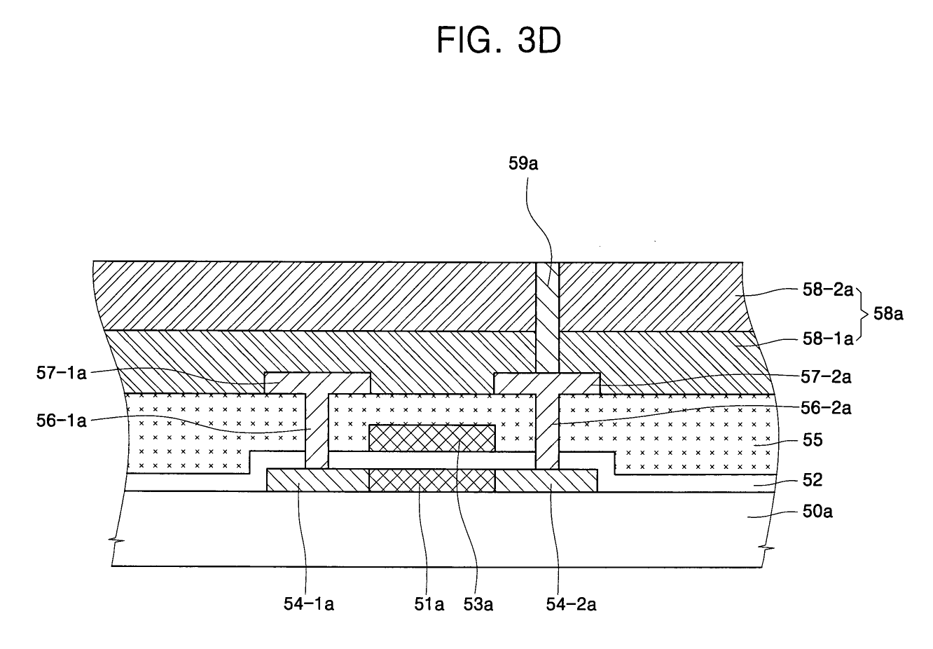

FIGS. 3A to 3D are cross-sectional views illustrating a method of manufacturing a thin film transistor according to a first embodiment of the present invention.

As illustrated in FIG. 3A, a buffer layer (not shown) may be formed of a silicon nitride layer or a silicon oxide layer on a transparent insulating substrate 50a such as a glass substrate or plastics. After forming a polysilicon layer on the buffer layer and pattering it, a semiconductor layer 51a having an island shape may be formed.

Next, a gate insulating layer 52a may be formed on the semiconductor layer 51a. A gate metal layer may be deposited and then patterned on the gate insulating layer 52a to form a gate 53a on the gate insulating layer 52a over the semiconductor layer 51a.

Next, one of the impurities having a conductive type, for example, n type or p type, may be ion-implanted into the semiconductor layer 51a to form source/drain areas 54-1a, 54-2a in the semiconductor layer 51a of both sides of the gate 53a.

As illustrated in FIG. 3B, an interlayer insulating layer 53a may be formed on the gate insulating layer 52a including the gate 53a.

As illustrated in FIG. 3c, a photosensitive or etching type organic planarization layer (not shown) may be deposited on the interlayer insulating layer 53a, and the photoresist pattern may be formed, and then, the contact hole/via hole 56-1a, 56-2a may be formed by etching a selected area to expose the source/drain areas 54-1a, 54-2a.

A metal material for the source/drain electrodes may be deposited on the interlayer insulating layer 55a having the contact hole/via hole 56-1a, 56-2a. The deposited source/drain metal may then be patterned to form the source/drain electrodes 57-1a, 57-2a each contacting with the source/drain areas 54-1a, 54-2a through the contact hole/via hole 56-1a, 56-2a.

As illustrated in FIG. 3D, an organic planarization layer 58-1a and an inorganic layer 58-2a may be sequentially formed on substantially the entire surface of the substrate to cover the source/drain electrodes 57-1a, 57-2a as a passivation layer 58a. After forming the photoresist pattern on the inorganic layer 58-2a, the contact hole or via hole 59a may be formed by etching a selected area to include the organic planarization layer 58-1a using the photoresist pattern as a mask.

As a result, one of the source/drain electrodes 56-1a, 56-2a may be electrically connected to a pixel electrode 60a through the contact hole or via hole 59a, and with this, a thin film transistor according to the first embodiment presented in the present invention may be manufactured

In particular, the passivation layer 58a formed on the source/drain electrodes 57-1a, 57-2a in the present invention may be formed of the organic planarization layer 58-1a and the inorganic layer 58-2a.

For a material that forms the organic planarization layer 58-1a, a typically used photosensitive organic polymer or etching type organic compound may be employed. The photosensitive organic polymer can use polyacrylate resin, epoxy resin, phenol resin, polyamides resin, polyimide resin, unsaturated polyester resin, polyphenylenether resin, and polyphenylenesulfide resin. It may be valuable to use polyacrylate resin and polyimide resin that may have good flatness. As the etching type organic compound, benzocyclobutene (BCB) may be most commonly used, which may have a flatness of at least 95%, and a small absorption rate and a good adhesion, and a light transmittance of at least 90%. Thereby the benzocyclobutene (BCB) may be most commonly used for an organic planarization layer.

Further, a material that forms the organic layer 58-2a can be a typically used SiNₓ or SiO₂. This organic layer 58-2a serves as a barrier that prevents moisture or impurities from being diffused from the external, and a passivation that protects the source/drain electrodes 57-1a, 57-2a. Further, the adhesion with the pixel electrode may be good, so that after encapsulation process, the adhesion may also be improved, thereby increasing the lifetime of the thin film transistor.

In one embodiment the etching process for forming the contact hole or via hole 59a can use a typical method, specifically, wet etching or dry etching. The dry etching process can use several methods, such as ion beam etching, RF sputtering etching, and reactive ion etching RIE, etc.

In particular, the passivation layer 58a including the organic planarization layer 58-1a and the inorganic layer 58-2a disclosed in the present invention can address the conventional problems such as delamination and cracking of the organic planarization layer 58-1a caused by the poor adhesion between the organic planarization layer 58-1a and the pixel electrode, using the organic planarization layer 58-1a under the pixel electrode. Further, by performing an etching process after depositing the photoresist pattern on the inorganic layer 58-2a, the organic planarization layer 58-1a that remains in the sealing portion and causes the delamination and crack can be all removed, resulting in the increase of the lifetime of the thin film transistor.

Further, in the present invention, the two or more etching processes applied in forming the contact hole or via hole 59a that connects the pixel electrode to one of the source/drain electrodes 57-1a, 57-2a can be replaced with one etching process, so that the number of masks may be reduced and the process may be simplified.

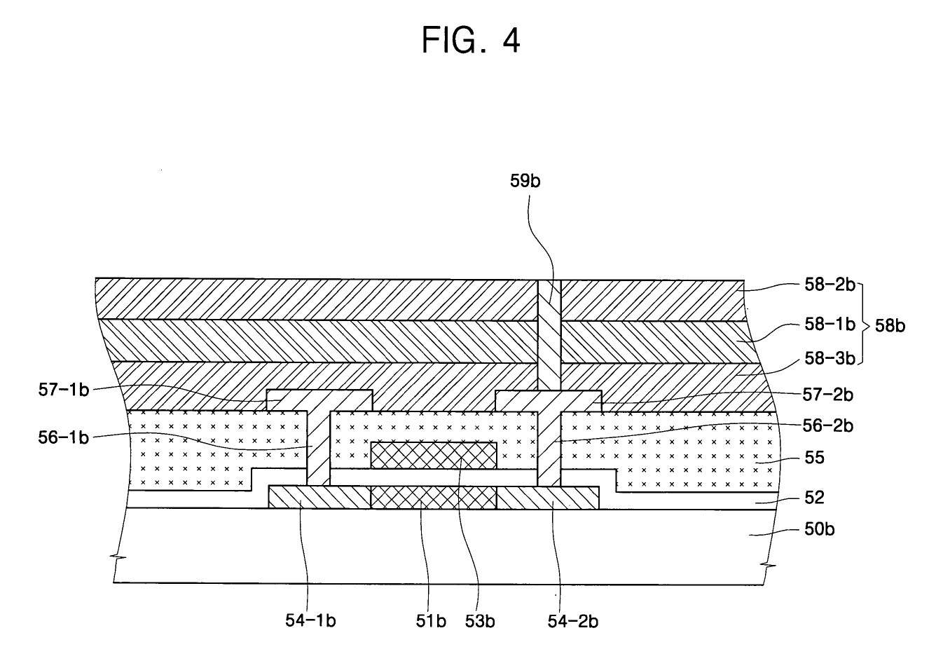

FIG. 4 may be a cross-sectional view illustrating a thin film transistor having source/drain electrodes according to a second embodiment of the present invention. The process of the thin film transistor having the structure of FIG. 4 may be performed using a method similar to that used in the first embodiment.

As illustrated in FIG. 4, for the thin film transistor according to the second embodiment of the present invention, a semiconductor layer 5 lb may be formed on an insulating substrate 50b, and a gate insulating layer 52b may be formed on the substrate 50b including the semiconductor layer 51b, and a gate 53b may be formed on the gate insulating layer 52b, and source/drain areas 54-1b, 54-2b may be formed in the semiconductor layer 51b of both sides of the gate 53b, and an interlayer insulating layer 55b may be formed on substantially the entire surface of the substrate and may have contact hole/via hole 56-1b, 56-2b that expose source/drain electrodes 57-1b, 57-2b, and the source/drain electrodes 57-1b, 57-2b that contact with the source/drain areas 54-1b, 54-2b through the contact hole/via hole 56-1b, 56-2b may be formed on the interlayer insulating layer 55b.

Next, a first inorganic layer 58-3b, an organic planarization layer 58-1b and a second inorganic layer 58-2b may be sequentially formed as a passivation layer 58b on substantially the entire surface of the substrate to cover the source/drain electrodes 57-1b, 57-2b, and a photoresist pattern may be formed on the second inorganic layer 58-2b, and then, the contact hole or via hole 59b may be formed by etching a selected area using the photoresist pattern as a mask. As a result, one of the source/drain electrodes 57-1b, 57-2b may be electrically connected to the pixel electrode through the contact hole or via hole 59b, and with this, the thin film transistor according to the second embodiment disclosed in the present invention may be manufactured.

The organic planarization layer 58-1b, the first and second inorganic layer 58-3b, 58-2b can be used with the material as described above, and In one embodiment the first inorganic layer 58-3b deposited under the organic planarization layer 58-1b may be the same or different from the second inorganic layer 58-2b deposited on the organic planarization layer 58-1b, and can be used with SiNₓ or SiO₂.

Like this, when the second inorganic layer 58-2b may be deposited on the organic planarization layer 58-1b as in the present invention, the adhesion with the pixel electrode of the organic electroluminescent device can be improved in the subsequent process, and the sealing adhesion in the encapsulation process can also be improved. Further, in forming the contact hole or via hole 59b that connects the source/drain electrodes 57-1b, 57-2b to the pixel electrode, two or more etching processes can be replaced with one etching process using only one mask, thereby reducing the number of masks and simplifying the process.

In particular, the first inorganic layer 58-3b may be additionally formed under the organic planarization layer 58-1b, so that the first inorganic layer 58-3b can prevent the source/drain electrodes 57-1b, 57-2b from the external impurities or moisture, and as a result, the lifetime of the thin film transistor can be increased.

Although the thin film transistor having a top gate structure in which a gate may be placed on source/drain areas may have been described above in the first and second embodiments of the present invention, the thin film transistor having a bottom-gate structure in which a gate may be placed under source/drain areas can appropriately apply the passivation layer disclosed herein.

Further, the disclosed thin film transistor can appropriately apply to the active matrix organic electroluminescent display.

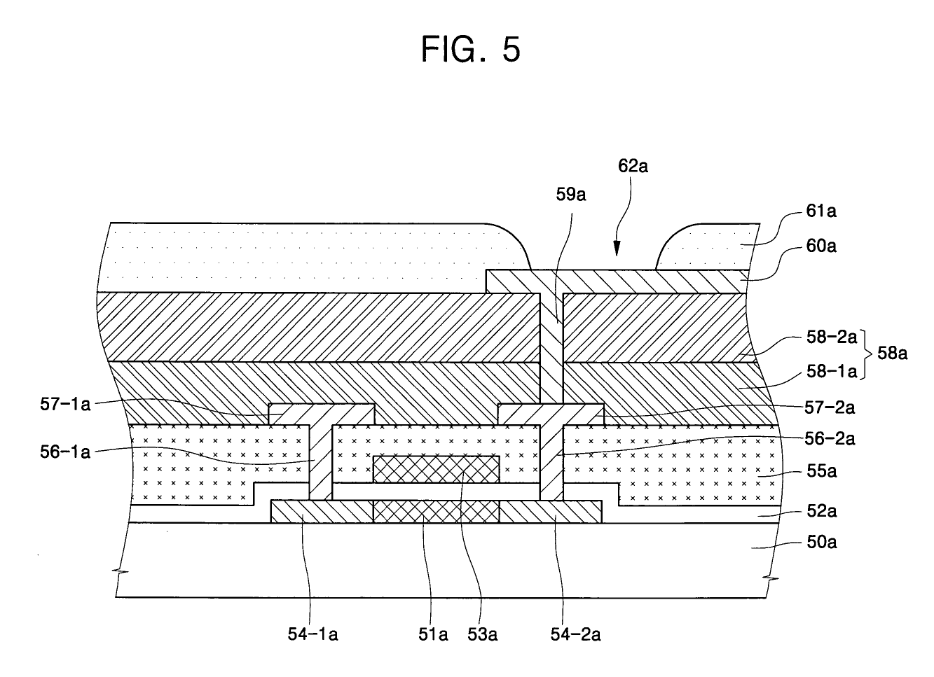

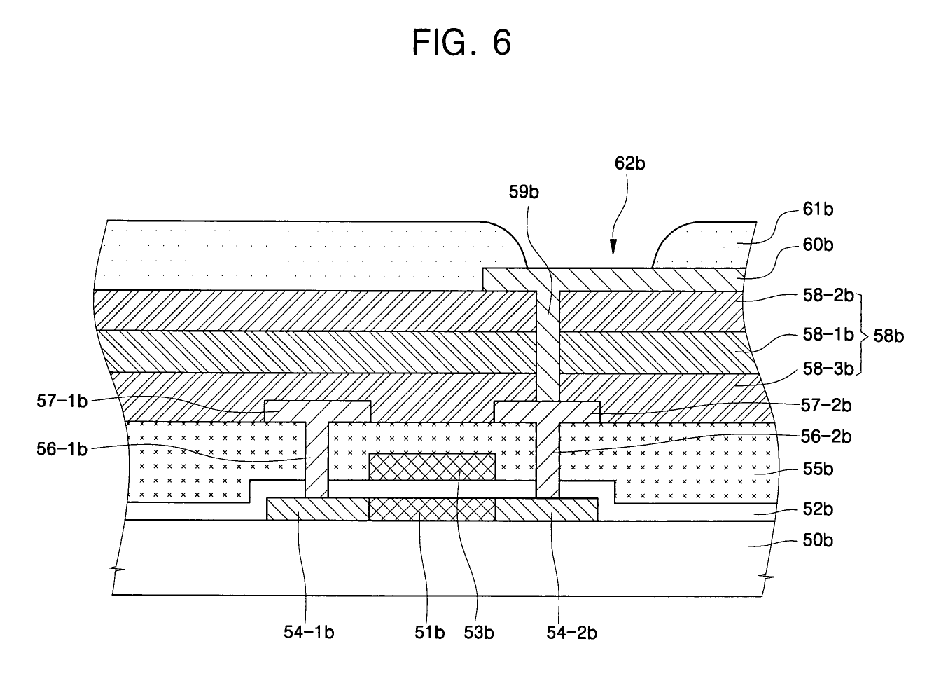

FIG. 5 may be a cross-sectional view when the thin film transistor according to the first embodiment applies to the active matrix organic electroluminescent display, and FIG. 6 may be a cross-sectional view when the thin film transistor according to the second embodiment applies to the active matrix organic electroluminescent display.

As illustrated in FIGS. 5 and 6, thin film transistors include semiconductor layers 51a, 51b, gates 53a, 53b, source/drain areas 54-1a, 54-2a, 54-1b, 54-2b and source/drain electrodes 57-1a, 57-2a, 57-1b, 57-2b, and include the contact hole or via hole 59a, 59b for each connecting pixel electrodes 60a, 60b with one of the source/drain electrodes 57-1a, 57-2a and one of the source/drain electrodes 57-1b, 57-2b, through a set of semiconductor processes in accordance with the first and second embodiments.

In one embodiment passivation layers 58a, 58b having the contact hole or via hole 59a, 59b therein for each connecting the pixel electrodes 60a, 60b with one of the source/drain electrodes 57-1a, 57-2a and one of the source/drain electrodes 57-1b, 57-2b may be formed on substantially the entire surface of the substrates 50a, 50b, having a structure in which the organic planarization layer 58-1a and the inorganic layer 58-2b may be formed (a first embodiment, refer to FIG. 5), or in which the first inorganic layer 58-3b, the organic planarization layer 58-1b and the second inorganic layer 58-2b may be formed (a second embodiment, refer to FIG. 6).

Next, the pixel electrodes 60a, 60b each electrically connected to one of the source/drain electrodes 57-1a, 57-2a and one of the source/drain electrodes 57-1b, 57-2b through the contact hole or via hole 59a, 59b may be formed on the passivation layers 58a, 58b.

Next, planarization insulating layers 61a, 61b having openings 62a, 62b that expose the pixel electrodes 60a, 60b may be formed on the passivation layer 58a, 58b covering edge portions of the pixel electrodes 60a, 60b.

Next, although not shown, the organic layer may be formed on the pixel electrode of the opening through the subsequent process, and the upper electrode may be formed on the insulating layer including the organic layer, and the active matrix organic electroluminescent display can be manufactured by encapsulating this with the encapsulating means, such as an insulating substrate.

As described above, according to the method of manufacturing the thin film transistor of the present invention, the contact hole or via hole that electrically connects the pixel electrode to one of the source/drain electrodes may be formed using one mask, thereby simplifying the overall process.

Further, the passivation layer having the contact hole or via hole includes an inorganic layer, thereby improving the adhesion with the pixel electrode and further improving the sealing adhesion in the encapsulating process.

Further, the inorganic layer may be selectively formed under the passivation layer, thereby protecting the source/drain electrodes from the external impurities and moisture so that the lifetime of the thin film transistor may be increased.

Although the present invention may have been described with reference to several embodiment, those skilled in the art will appreciate that a change and a modification can be made without departing from the scope and the area of the present invention described in the following claims.

1. A thin film transistor, comprising:
a passivation layer formed between a pixel electrode and source/drain electrodes of a thin film transistor having a semiconductor layer, a gate, source/drain areas and the source/drain electrodes,
wherein the passivation layer includes an inorganic layer and an organic planarization layer at least partially below the inorganic layer,
wherein a portion of the inorganic layer directly contacts with the pixel electrode, and
wherein the organic planarization layer contacts the source/drain electrodes.

2. The thin film transistor according to claim 1, wherein the passivation layer further includes another inorganic layer between the organic planarization layer and the source/drain electrodes.

3. The thin film transistor according to claims 1, wherein the inorganic layer includes at least a silicon nitride layer (SiNₓ) or a silicon oxide layer (SiO₂).

4. The thin film transistor according to claim 1, wherein the organic planarization layer is selected from a group consisting of polyacrylate resin, epoxy resin, phenol resin, polyamide resin, polyimide resin, unsaturated polyester resin, polyphenylenether resin, polyphenylenesulfide resin, and benzocyclobutene (BCB).

5. The thin film transistor according to claim 1, wherein the thin film transistor has a top-gate structure or a bottom-gate structure.

6. The thin film transistor according to claim 1, wherein the thin film transistor is a driving thin film transistor in a unit pixel of an organic electroluminescent display.

7. A thin film transistor, comprising:
a semiconductor layer formed on a substrate;
a gate insulating layer formed on the substrate having the semiconductor layer;
a gate electrode formed on a gate insulating layer over the semiconductor layer;
source/drain areas formed in the semiconductor layer of both sides of the gate;
an interlayer insulating layer formed on an entire surface of the substrate and having a contact hole/via hole that exposes source/drain electrodes;
the source/drain electrodes formed on the interlayer insulating layer and contacting with the source/drain areas through the contact hole/via hole and; and
a passivation layer having a contact hole or a via hole that exposes one of the source/drain electrodes and having an organic planarization layer and an inorganic layer sequentially formed on substantially the entire surface of the substrate.

8. The thin film transistor according to claim 7, wherein the organic planarization layer is selected from a group consisting of polyacrylate resin, epoxy resin, phenol resin, polyamide resin, polyimide resin, unsaturated polyester resin, polyphenylenether resin, polyphenylenesulfide resin, and benzocyclobutene (BCB).

9. The thin film transistor according to claim 7, wherein the inorganic layer includes SiNₓ or SiO₂.

10. The thin film transistor according to claim 7, wherein the thin film transistor has a top-gate structure or a bottom-gate structure.

11. The thin film transistor according to claim 7, wherein the thin film transistor is a driving thin film transistor in a unit pixel of an organic electroluminescent display.

12. A thin film transistor, comprising:
a semiconductor layer formed on a substrate;
a gate insulating layer formed on the substrate having the semiconductor layer;
a gate formed on a gate insulating layer over the semiconductor layer;
source/drain areas formed in the semiconductor layer of both sides of the gate;
an interlayer insulating layer formed on substantially the entire surface of the substrate and having a contact hole/via hole that exposes source/drain electrodes;
the source/drain electrodes formed on the interlayer insulating layer and contacting with the source/drain areas through the contact hole/via hole; and
a passivation layer having a contact hole or a via hole that exposes one of the source/drain electrodes and having a first inorganic layer, an organic planarization layer and a second inorganic layer sequentially formed on substantially the entire surface of the substrate.

13. The thin film transistor according to claim 12, wherein the organic planarization layer is selected from a group consisting of polyacrylate resin, epoxy resin, phenol resin, polyamide resin, polyimide resin, unsaturated polyester resin, polyphenylenether resin, polyphenylenesulfide resin, and benzocyclobutene (BCB).

14. The thin film transistor according to claim 12, wherein the first and second inorganic layers differ from each other, and include SiNₓ or SiO₂.

15. The thin film transistor according to claim 12, wherein the thin film transistor has a top-gate structure or a bottom-gate structure.

16. The thin film transistor according to claim 12, wherein the thin film transistor is a driving thin film transistor in a unit pixel of an organic electroluminescent display.

17. A method of manufacturing a thin film transistor, comprising:
forming a semiconductor layer on a substrate;
forming a gate insulating layer on the substrate having the semiconductor layer;
forming a gate on the gate insulating layer placed on the semiconductor layer;
ion-implanting impurities into the semiconductor layer to form source/drain areas in the semiconductor layer of both sides of the gate;
forming an interlayer insulating layer on an entire surface of the substrate;
etching a selected area of the interlayer insulating layer to form a contact hole/via hole that exposes the source/drain areas;
forming source/drain electrodes that contacts with the source/drain areas through the contact hole/via hole on the interlayer insulating layer;
sequentially forming an organic planarization layer and an inorganic layer as a passivation layer on substantially the entire surface of the substrate; and
etching a selected area of the organic planarization layer and the organic layer to form a contact hole or a via hole that exposes one of the source/drain electrodes.

18. The method according to claim 17, wherein the etching process of the passivation layer is performed by a dry etching process.

19. The method according to claim 18, wherein the dry etching process is performed by a method of one of ion beam etching, RF sputtering etching and reactive ion etching RIE.

20. A method of manufacturing a thin film transistor, comprising:
forming a semiconductor layer on a substrate;
forming a gate insulating layer on the substrate having the semiconductor layer;
forming a gate on the gate insulating layer placed on the semiconductor layer;
ion-implanting high-concentration impurities into the semiconductor layer to form source/drain areas in the semiconductor layer of both sides of the gate;
forming an interlayer insulating layer on an entire surface of the substrate;
etching a selected area of the interlayer insulating layer to form a contact hole/via hole that exposes the source/drain areas;
forming source/drain electrodes that contact with the source/drain areas through the contact hole/via hole on the interlayer insulating layer;
sequentially forming a first inorganic layer, an organic planarization layer and a second inorganic layer as a passivation layer on substantially the entire surface of the substrate; and
etching a selected area of the first inorganic layer, the organic planarization layer and the second inorganic layer to form a contact hole or a via hole that exposes one of the source/drain electrodes.

21. The method according to claim 20, wherein the etching process of the passivation layer is performed by a dry etching process.

22. The method according to claim 20, wherein the dry etching process is performed by a method of one of ion beam etching, RF sputtering etching and reactive ion etching RIE.

23. An active matrix organic electroluminescent display, comprising:
a semiconductor layer formed on a substrate;
a gate insulating layer formed on the substrate having the semiconductor layer;
a gate formed on the gate insulating layer over the semiconductor layer;
source/drain areas formed in the semiconductor layer of both sides of the gate;
an interlayer insulating layer formed on an entire surface of the substrate and having a contact hole/via hole that exposes source/drain electrodes;
source/drain electrodes formed on the interlayer insulating layer and contacting with the source/drain areas through the contact hole/via hole;
a passivation layer having a contact hole or a via hole that exposes one of the source/drain electrodes and having an organic planarization layer and an inorganic layer sequentially formed on substantially the entire surface of the substrate;
a planarization layer formed on substantially the entire surface of the substrate and having an opening; and
a pixel electrode formed to extend through a contact hole or a via hole from one of the source/drain electrodes and exposed through the opening.

24. The active matrix organic electroluminescent display according to claim 23, wherein the organic planarization layer is selected from a group consisting of polyacrylate resin, epoxy resin, phenol resin, polyamide resin, polyimide resin, unsaturated polyester resin, polyphenylenether resin, polyphenylenesulfide resin, and benzocyclobutene (BCB).

25. The active matrix organic electroluminescent display according to claim 23, wherein the inorganic layer includes SiNₓ or SiO₂.

26. The active matrix organic electroluminescent display according to claim 23, wherein the contact hole or via hole that connects the pixel electrode to one of the source/drain electrodes does not have a step.

27. An active matrix organic electroluminescent display, comprising:
a semiconductor layer formed on a substrate;
a gate insulating layer formed on the substrate having the semiconductor layer;
a gate formed on the gate insulating layer over the semiconductor layer;
source/drain areas formed in the semiconductor layer of both sides of the gate;
an interlayer insulating layer formed on an entire surface of the substrate and having a contact hole/via hole that exposes source/drain electrodes;
source/drain electrodes formed on the interlayer insulating layer and contacting with the source/drain areas through at least one of the contact hole and the via hole;
a passivation layer having a contact hole or a via hole that exposes one of the source/drain electrodes wherein a first inorganic layer, an organic planarization layer and a second inorganic layer is sequentially formed on substantially the entire surface of the substrate as the passivation layer;
a planarization layer formed on substantially the entire surface of the substrate and having an opening; and
a pixel electrode formed to extend through a contact hole or a via hole from one of the source/drain electrodes and exposed through the opening.

28. The active matrix organic electroluminescent display according to claim 27, wherein the organic planarization layer is selected from a group consisting of polyacrylate resin, epoxy resin, phenol resin, polyamide resin, polyimide resin, unsaturated polyester resin, polyphenylenether resin, polyphenylenesulfide resin, and benzocyclobutene (BCB).

29. The active matrix organic electroluminescent display according to claim 27, wherein the first and second inorganic layers differ from each other, and include SiNₓ or SiO₂.

30. The active matrix organic electroluminescent display according to claim 27, wherein the contact hole or via hole that connects the pixel electrode to one of the source/drain electrodes does not have a step.
